(19) United States
(12) Patent Application Publication
(10) Pub. No.: US 2022/0330457 A1
(43) Pub. Date: Oct. 13, 2022

(54) HEAT DISSIPATION STRUCTURE AND ELECTRONIC DEVICE INCLUDING THE SAME

(71) Applicant: Samsung Electronics Co., Ltd., Suwon-si, Gyeonggi-do (KR)

(72) Inventors: Joseph AHN, Suwon-si (KR); Kyungha KOO, Suwon-si (KR); Hongki MOON, Suwon-si (KR)

(21) Appl. No.: 17/435,928

(22) PCT Filed: Sep. 1, 2021
(86) PCT No.: PCT/KR2021/011761

§ 371 Date: Sep. 2, 2021

(30) Foreign Application Priority Data
Sep. 2, 2020 (KR) 10-2020-0111453

(51) Int. Cl. H05K 7/20; F28D 15/02

(52) U.S. Cl. CPC H05K 7/20336; F28D 15/0233

(57) ABSTRACT

A vapor chamber and an electronic device are provided. The vapor chamber includes a first sheet including a first flat portion and a first bending portion bent, at an edge of the first flat portion, to be inclined at a first angle for the first flat portion, a second sheet including a second flat portion and a second bending portion bent, at an edge of the second flat portion, to be inclined at a second angle for the second flat portion, and a side portion formed by bonding the first bending portion and the second bending portion. A bonding surface between the first bending portion and the second bending portion may be disposed to be inclined from or perpendicular to an outer surface of the side portion.

### CROSS-REFERENCE TO RELATED APPLICATION(S)

This application is a U.S. National Stage application under 35 U.S.C. § 371 of an International application number PCT/KR2021/011761, filed on Sep. 1, 2021, which is based on and claims priority of a Korean patent application number 10-2020-0111453, filed on Sep. 2, 2020, in the Korean Intellectual Property Office, the disclosure of which is incorporated by reference herein in its entirety.

### TECHNICAL FIELD

The disclosure relates to an electronic device. More particularly, the disclosure relates to an electronic device including a heat dissipation structure, such as a vapor chamber.

### BACKGROUND ART

Developing electronics, and information and communication technologies integrate various functionalities into a single electronic device. For example, smartphones pack the functionalities of a sound player, imaging device, and scheduler, as well as the communication functionality and, on top of that, may implement more various functions by having applications installed thereon. An electronic device may not only its equipped applications or stored files but also access, wiredly or wirelessly, a server or another electronic device to receive, in real-time, various pieces of information.

With increased degree of integration, electronic devices are able to perform various functions despite their reduced size. As the electronic device is highly integrated, a controlling component (e.g., a processor or communication module) or an electronic component (e.g., an antenna module) for wireless communication in the electronic device may become more compact or advanced. For example, various electronic components, advanced or integrated, may exert enhanced performance.

The above information is presented as background information only to assist with an understanding of the disclosure. No determination has been made, and no assertion is made, as to whether any of the above might be applicable as prior art with regard to the disclosure.

### DETAILED DESCRIPTION

### Technical Problem

Such an electronic component or electronic device may exhibit stable operating performance in an appropriate temperature environment. However, integrated and advanced electronic components may generate heat while operating, causing deterioration of operating performance. This may result in a reduction in power efficiency in signal processing or controlling. Desktop computers, laptop computers, or such electronic devices may quickly cool down their internal space or electronic components (hereinafter, ‘heat generating components’) using a mechanical device, e.g., a cooling fan. However, it may be hard to equip small portable or wearable electronic devices with a cooling device. Such electronic device may thus include a heat dissipation structure (e.g., a heat pipe and/or vapor chamber) to dissipate the heat generated from electronic components (e.g., discharge the heat to the outside).

Aspects of the disclosure are to address at least the above-mentioned problems and/or disadvantages and to provide at least the advantages described below. Accordingly, an aspect of the disclosure is to provide a heat dissipation structure, e.g., a vapor chamber, which creates a stable operating environment and/or an electronic device including the same.

Another aspect of the disclosure is to provide a vapor chamber that is easy to install in a narrow space while having stable mechanical strength (stiffness or strength) and/or an electronic device.

Additional aspects will be set forth in part in the description which follows and, in part, will be apparent from the description, or may be learned by practice of the presented embodiments.

### Technical Solution

In accordance with an aspect of the disclosure, a vapor chamber and/or an electronic device is provided. The vapor chamber includes a first sheet including a first flat portion and a first bending portion bent, at an edge of the first flat portion, to be inclined at a first angle for the first flat portion, a second sheet including a second flat portion and a second bending portion bent, at an edge of the second flat portion, to be inclined at a second angle for the second flat portion, and a side portion formed by bonding the first bending portion and the second bending portion. A bonding surface between the first bending portion and the second bending portion may be disposed to be inclined from or perpendicular to an outer surface of the side portion.

In accordance with another aspect of the disclosure, an electronic device is provided. The electronic device includes a housing, a printed circuit board received in the housing, at least one heat generating component disposed on the printed circuit board, and at least one vapor chamber disposed adjacent to the at least one heat generating component and configured to absorb, in a first direction, heat generated from the at least one heat generating component and transfer or discharge the heat in a second direction different from the first direction. The at least one vapor chamber may include a first sheet including a first flat portion and a first bending portion bent, at an edge of the first flat portion, to be inclined at a first angle for the first flat portion, a second sheet including a second flat portion and a second bending portion bent, at an edge of the second flat portion, to be inclined at a second angle for the second flat portion, and a side portion formed by bonding the first bending portion and the second bending portion. A bonding surface between the first bending portion and the second bending portion may be disposed to be inclined from or perpendicular to an outer surface of the side portion.

### Advantageous Effects

According to various embodiments of the disclosure, the at least one vapor chamber may be manufactured by bonding a pair of edge-bent sheets to face each other and irradiating a laser beam from the side surface thereof. For example, the at least one vapor chamber may be formed of a material including stainless steel and may thus have a sufficient mechanical strength although manufactured in a small size. Further, the at least one vapor chamber may have sufficient bonding strength between the pair of sheets through laser welding. In an embodiment of the disclosure, the at least one vapor chamber is made in a small size to be easy to install in a narrow space, thereby contributing to reducing the size of the electronic device. Further, the at least one vapor chamber may have sufficient mechanical strength to be easily handled in installation. Other various effects may be provided directly or indirectly in the disclosure.

Other aspects, advantages, and salient features of the disclosure will become apparent to those skilled in the art from the following detailed description, which, taken in conjunction with the annexed drawings, discloses various embodiments of the disclosure.

### DESCRIPTION OF THE DRAWINGS

The above and other aspects, features, and advantages of certain embodiments of the disclosure will be more apparent from the following description taken in conjunction with the accompanying drawings, in which:

FIG. 1 is a front perspective view illustrating an electronic device according to an embodiment of the disclosure;

FIG. 2 is a rear perspective view illustrating an electronic device of FIG. 1 according to an embodiment of the disclosure;

FIG. 3 is an exploded perspective view illustrating an electronic device of FIG. 1 according to an embodiment of the disclosure;

FIG. 4 is an exploded perspective view illustrating a vapor chamber according to an embodiment of the disclosure;

FIG. 5 is a perspective view illustrating a vapor chamber according to an embodiment of the disclosure;

FIG. 6 is a cross-sectional view illustrating a configuration of a vapor chamber according to an embodiment of the disclosure;

FIG. 7 is a view illustrating a configuration of sheets of a vapor chamber according to an embodiment of the disclosure;

FIGS. 8, 9, 10, 11, 12, 13, 14, and 15 are views illustrating a bonding surface forming structure of a vapor chamber according to various embodiments of the disclosure;

FIG. 16 is a view illustrating a configuration in which a vapor chamber is disposed in an electronic device according to an embodiment of the disclosure;

FIG. 17 is a view illustrating a vacuum chuck among equipment for manufacturing a vapor chamber according to an embodiment of the disclosure;

FIG. 18 is a view illustrating equipment for manufacturing a vapor chamber according to an embodiment of the disclosure; and

FIG. 19 is a block diagram illustrating an electronic device in a network environment according to an embodiment of the disclosure.

Throughout the drawings, like reference numerals will be understood to refer to like parts, components, and structures.

### MODE FOR INVENTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

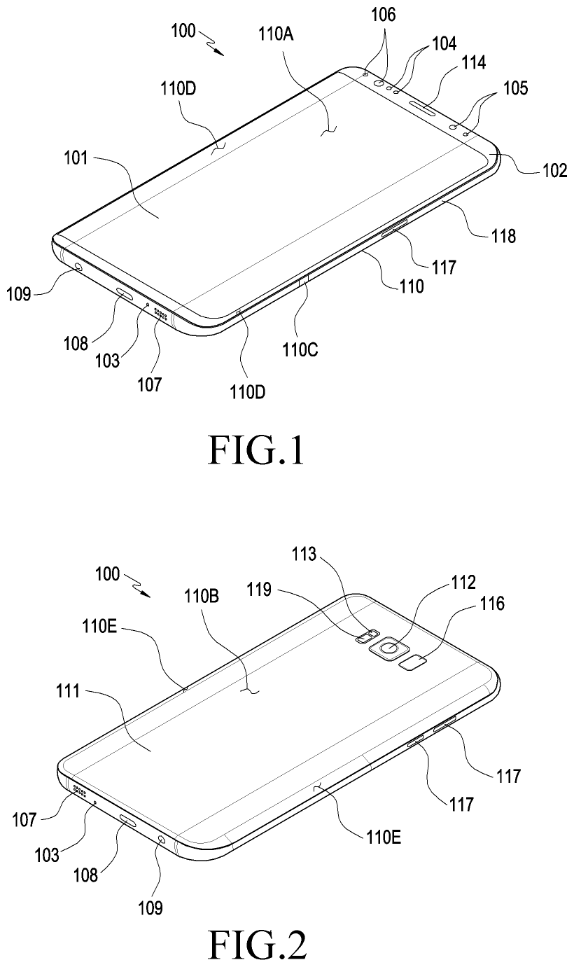

FIG. 1 is a front perspective view illustrating an electronic device according to an embodiment of the disclosure.

FIG. 2 is a rear perspective view illustrating an electronic device as illustrated in FIG. 1 according to an embodiment of the disclosure.

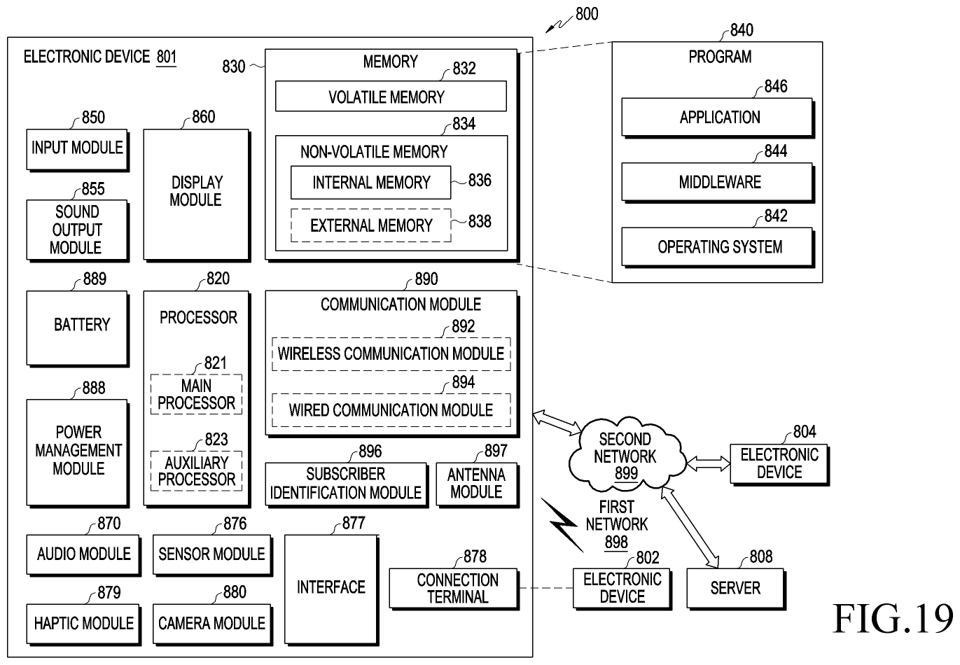

Referring to FIGS. 1 and 2, according to an embodiment of the disclosure, an electronic device 100 (e.g., external electronic device 801, 802, or 804 or server 808 of FIG. 19) may include a housing 110 including a first (or front) surface 110A, a second (or rear) surface 110B, and a side surface 110C surrounding a space between the first surface 110A and the second surface 110B. According to another embodiment (not shown), the housing may denote a structure forming part of the first surface 110A, the second surface 110B, and the side surface 110C of FIG. 1. According to an embodiment of the disclosure, the first surface 110A may be formed by a front plate 102 (e.g., a glass plate or polymer plate with various coat layers) at least part of which is substantially transparent. The second surface 110B may be formed by a rear plate 111 that is substantially opaque. The rear plate 111 may be formed of, e.g., laminated or colored glass, ceramic, polymer, metal (e.g., aluminum, stainless steel (STS), or magnesium), or a combination of at least two thereof. The side surface 110C may be formed by a bezel structure (or a “side structure”) 118 that couples to the front plate 102 and the rear plate 111 and includes a metal and/or polymer. According to an embodiment of the disclosure, the rear plate 111 and the side surface structure 118 may be integrally formed together and include the same material (e.g., a metal, such as aluminum).

In the illustrated embodiment of the disclosure, the front plate 102 may include two first areas 110D, which are bent, and seamlessly extend, from the first surface 110A toward the rear plate 111, at two opposite long edge ends of the front plate 102. In the illustrated embodiment (see FIG. 2), the rear plate 111 has two second areas 110E, which are bent, and seamlessly extend, from the second surface 110B toward the front plate 102, at two opposite long edge ends. In an embodiment of the disclosure, the front plate 102 (or the rear plate 111) may include only one of the first areas 110D (or the second areas 110E). In another embodiment of the disclosure, some of the first areas 110D or the second areas 110E may not be included. In the above embodiments of the disclosure, when viewed from a side of the electronic device 100, the side structure 118 may have a first thickness (or width) at a side surface which does not include the first areas 110D or the second areas 110E and a second thickness, smaller than the first thickness, at a side surface which includes the first areas 110D or the second areas 110E.

According to an embodiment of the disclosure, the electronic device 100 may include at least one of a display 101 (e.g., the display module 860 of FIG. 19), audio modules 103, 107, and 114 (e.g., the input module 850, a sound output module 855, and/or audio module 870 of FIG. 19), sensor modules 104, 116, and 119 (e.g., the sensor module 876 of FIG. 19), camera modules 105, 112, and 113 (e.g., the camera module 880 of FIG. 19), a key input device 117 (e.g., the input module 850 of FIG. 19), a light emitting device 106, and connector holes 108 and 109. According to an embodiment of the disclosure, the electronic device 100 may exclude at least one (e.g., the key input device 117 or the light emitting device 106) of the components or may add other components.

According to an embodiment of the disclosure, the display 101 may be exposed through, e.g., a majority portion of the front plate 102. In some embodiments of the disclosure, at least a portion of the display 101 may be exposed through the front plate 102 forming the first surface 110A and the first areas 110D of the side surface 110C. According to an embodiment of the disclosure, the edge of the display 101 may be formed to be substantially the same in shape as an adjacent outer edge of the front plate 102. According to an embodiment (not shown), the interval between the outer edge of the display 101 and the outer edge of the front plate 102 may remain substantially even to give a larger area of exposure the display 101.

According to an embodiment (not shown) of the disclosure, the screen display region of the display 101 may have a recess or opening in a portion thereof, and at least one or more of the audio module 114, sensor module 104, camera module 105, and light emitting device 106 may be aligned with the recess or opening. According to an embodiment (not shown), at least one or more of the audio module 114, sensor module 104, camera module 105, fingerprint sensor 116, and light emitting device 106 may be included on the rear surface of the screen display region of the display 101.

In another embodiment (not shown), the display 101 may include at least one of an audio module 114, a sensor module 104, a camera module 105, and a light emitting device 106 on the rear surface of the screen display area (e.g., the first surface 110A and the first areas 110D). For example, the electronic device 100 may have the camera module 105 disposed on the rear surface of at least one of the first surface 110A (e.g., the front surface) and/or the side surface 110C (e.g., the first area 110D) to face the first surface 110A and/or the side surface 110C. For example, the camera module 105 may include an under display camera (UDC) that is not exposed to the screen display area.

According to another embodiment (not shown), the display 101 may be disposed to be coupled with, or adjacent, a touch detecting circuit, a pressure sensor capable of measuring the strength (pressure) of touches, and/or a digitizer for detecting a magnetic field-type stylus pen. In some embodiments of the disclosure, at least a portion of the sensor modules 104 and 119, and/or at least a portion of the key input device 117 may be disposed in the first areas 110D and/or the second areas 110E.

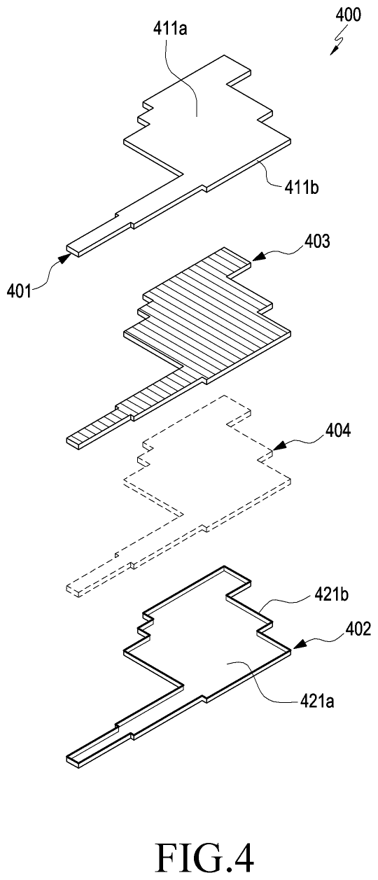

In another embodiment (not shown), the display 101 may include a display that is disposed to be slidable and provides a screen (e.g., a screen display area). For example, the screen display area of the electronic device 100 is an area that is visually exposed and enables an image to be output. The electronic device 100 may adjust the screen display area according to movement of a sliding plate (not shown) or movement of the display 101. For example, the electronic device 100 may include a rollable electronic device configured to selectively expand the screen display area as at least a portion (e.g., the housing) of the electronic device 100 is operated to be at least partially slidable. For example, the display 101 may be referred to as a slide-out display or an expandable display. According to an embodiment of the disclosure, a heat dissipation structure (e.g., the vapor chamber 400 of FIG. 4), which is disposed under the display 101 and dissipates heat to the outside, may be moved according to a change in the state of the display 101 (e.g., a shrunken state or expanded state). For example, according to the movement of a first supporting member (e.g., the first supporting member 311 of FIG. 16) inside the electronic device 100, heat dissipation structure disposed between the display 101 and the first supporting member may also be moved and may cool electronic components.

According to an embodiment of the disclosure, the audio modules 103, 107, and 114 may include a microphone hole 103 and speaker holes 107 and 114. A microphone for acquiring external sounds may be disposed in the microphone hole 103. In some embodiments of the disclosure, a plurality of microphones may be disposed to detect the direction of the sound. The speaker holes 107 and 114 may include an external speaker hole 107 and a phone receiver hole 114. In some embodiments of the disclosure, the speaker holes 107 and 114 and the microphone hole 103 may be implemented as a single hole, or a speaker may be included without the speaker holes 107 and 114 (e.g., a piezo speaker).

According to an embodiment of the disclosure, the sensor modules 104, 116, and 119 may generate an electrical signal or data value corresponding to an internal operating state or external environmental state of the electronic device 100. For example, the sensor modules 104, 116, and 119 may include a first sensor module 104 (e.g., a proximity sensor) and/or a second sensor module (not shown) (e.g., a fingerprint sensor), which is disposed on the first surface 110A of the housing 110, and/or a third sensor module 119 (e.g., a heartrate monitor (HRM) sensor) and/or a fourth sensor module 116 (e.g., a fingerprint sensor) disposed on the second surface 110B of the housing 110. The fingerprint sensor may be disposed on the second surface 110B as well as the first surface 110A (e.g., the display 101) of the housing 110. The electronic device 100 may include a sensor module not shown, e.g., at least one of a gesture sensor, a gyro sensor, a barometric sensor, a magnetic sensor, an acceleration sensor, a grip sensor, a color sensor, an infrared (IR) sensor, a biometric sensor, a temperature sensor, a humidity sensor, or an illuminance sensor.

According to an embodiment of the disclosure, the camera modules 105, 112, and 113 may include a first camera device 105 disposed on the first surface 110A of the electronic device 100, a second camera device 112 disposed on the second surface 110B, and/or a flash 113. The camera devices 105 and 112 may include one or more lenses, an image sensor, and/or an image signal processor (e.g., the main processor 821 or the auxiliary processor 823 of FIG. 19). The flash 113 may include, e.g., a light emitting diode (LED) or a xenon lamp. According to an embodiment of the disclosure, two or more lenses (an infrared (IR) camera, a wide-angle lens, and a telescopic lens) and image sensors may be disposed on one surface of the electronic device 100.

According to an embodiment of the disclosure, the key input device 117 may be disposed on the side surface 110C of the housing 110. According to an embodiment of the disclosure, the electronic device 100 may exclude all or some of the above-mentioned key input devices 117 and the excluded key input devices 117 may be implemented in other forms, e.g., as soft keys, on the display 101. According to an embodiment of the disclosure, the key input device may include the sensor module 116 disposed on the second surface 110B of the housing 110.

According to an embodiment of the disclosure, the light emitting device 106 may be disposed on the first surface 110A of the housing 110, for example. The light emitting device 106 may provide, e.g., information about the state of the electronic device 100 in the form of light. According to an embodiment of the disclosure, the light emitting device 106 may provide a light source that interacts with, e.g., the camera module 105. The light emitting device 106 may include, e.g., a light emitting device (LED), an infrared (IR) LED, or a xenon lamp.

According to an embodiment of the disclosure, the connector holes 108 and 109 may include a first connector hole 108 for receiving a connector (e.g., a universal serial bus (USB) connector) (e.g., a connecting terminal 878 of FIG. 19) for transmitting or receiving power and/or data to/from an external electronic device and/or a second connector hole (e.g., an earphone jack) 109 for receiving a connector for transmitting or receiving audio signals to/from the external electronic device.

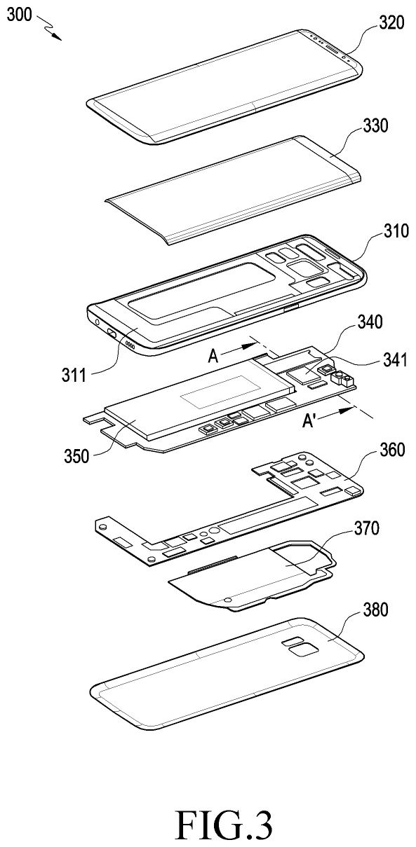

FIG. 3 is an exploded perspective view illustrating an electronic device of FIG. 1 according to an embodiment of the disclosure.

Referring to FIG. 3, an electronic device 300 (e.g., the external electronic device 801, 802, or 804 of FIG. 19) may include a side structure 310, a first supporting member 311 (e.g., a bracket), a front plate 320, a display 330 (e.g., the display module 860 of FIG. 19), a printed circuit board 340 (e.g., a printed circuit board (PCB), printed board assembly (PBA), flexible PCB (FPCB), or rigid-flexible (RFPCB)), a battery 350 (e.g., the battery 889 of FIG. 19), a second supporting member 360 (e.g., a rear case), an antenna 370 (e.g., an antenna module 897 of FIG. 19), and a rear plate 380. According to an embodiment of the disclosure, the electronic device 300 may exclude at least one (e.g., the first supporting member 311 or the second supporting member 360) of the components or may add other components. According to an embodiment (not shown), the electronic device 300 may include at least one hinge structure to thereby have a structure in which a housing split into a plurality of areas is folded. For example, according to a change in the state of the hinge structure (e.g., a folded state, an intermediate state, or an unfolded state), the state of the display operatively connected to the housing may change. For example, the first display corresponding to the first housing and the second display corresponding to the second housing may be changed to face each other or to be spaced apart from each other. According to an embodiment of the disclosure, at least one of the components of the electronic device 300 may be the same or similar to at least one of the components of the electronic device 100 of FIG. 1 or 2 and no duplicate description is made below.

According to an embodiment of the disclosure, the first supporting member 311 may be disposed inside the electronic device 300 to be connected with the side structure 310 or integrated with the side structure 310. The first supporting member 311 may be formed of, e.g., a metal and/or non-metallic material (e.g., polymer). The display 330 may be bonded onto one surface of the first supporting member 311, and the printed circuit board 340 may be bonded onto the opposite surface of the first supporting member 311.

According to an embodiment of the disclosure, a processor (e.g., a processor 820 of FIG. 19), a memory (e.g., a memory 830 of FIG. 19), and/or an interface (e.g., an interface 877 of FIG. 19) may be mounted on the printed circuit board 340. The processor may include one or more of, e.g., a central processing unit, an application processor, a graphic processing device, an image signal processing, a sensor hub processor, or a communication processor. In an embodiment of the disclosure, the processor or communication module (e.g., a communication module 890 of FIG. 19) may be mounted in an electronic component, such as the integrated circuit chip 341, and disposed on the printed circuit board 340. A plurality of electronic components may be disposed on the printed circuit board 340, and some of the electronic components, e.g., the integrated circuit chip 341 in which the processor or communication module is mounted, may generate heat while operating. As mentioned above, the heat generated by the heat generating component (e.g., the integrated circuit chip 341) reduces its own operating performance or the power efficiency of the electronic device 300. The electronic device 300 may include a heat dissipation structure, such as a heat transfer member, a heat pipe, and/or a vapor chamber, thereby rapidly dissipating or dispersing the heat generated from the heat generating component.

According to an embodiment of the disclosure, the electronic device 300 may include a heat dissipation structure (e.g., a vapor chamber and/or a heat pipe). For example, a vapor chamber (e.g., the vapor chamber 400 of FIG. 4) may dissipate the heat generated from electronic components (e.g., the integrated circuit chip 341) to another area or space inside the electronic device 300 (e.g., inside the housing 110 of FIG. 1). In one embodiment of the disclosure, the vapor chamber 400 may be formed in a structure to be at least partially disposed adjacent to the surface of the integrated circuit chip 341. In one embodiment of the disclosure, the vapor chamber 400 may cover at least a portion of the integrated circuit chip 341. For example, when viewed from a designated direction (e.g., when viewed from the front), at least a portion of the vapor chamber 400 may overlap the integrated circuit chip 341.

According to an embodiment of the disclosure, the memory may include, e.g., a volatile or non-volatile memory.

According to an embodiment of the disclosure, the interface may include, for example, a high definition multimedia interface (HDMI), a universal serial bus (USB) interface, a secure digital (SD) card interface, and/or an audio interface. The interface may electrically or physically connect, e.g., the electronic device 300 with an external electronic device and may include a USB connector, an SD card/multimedia card (MMC) connector, or an audio connector.

According to an embodiment of the disclosure, the battery 350 may be a device for supplying power to at least one component of the electronic device 300. The battery 189 may include, e.g., a primary cell which is not rechargeable, a secondary cell which is rechargeable, or a fuel cell. At least a portion of the battery 350 may be disposed on substantially the same plane as the printed circuit board 340. The battery 350 may be integrally or detachably disposed inside the electronic device 300.

According to an embodiment of the disclosure, the antenna 370 may be disposed between the rear plate 380 and the battery 350. The antenna 370 may include, e.g., a near-field communication (NFC) antenna, a wireless charging antenna, and/or a magnetic secure transmission (MST) antenna. The antenna 370 may perform short-range communication with, e.g., an external device or may wirelessly transmit or receive power necessary for charging. According to another embodiment of the disclosure, an antenna structure may be formed by a portion or combination of the side structure 310 and/or the first supporting member 311.

FIG. 4 is an exploded perspective view illustrating a vapor chamber according to an embodiment of the disclosure.

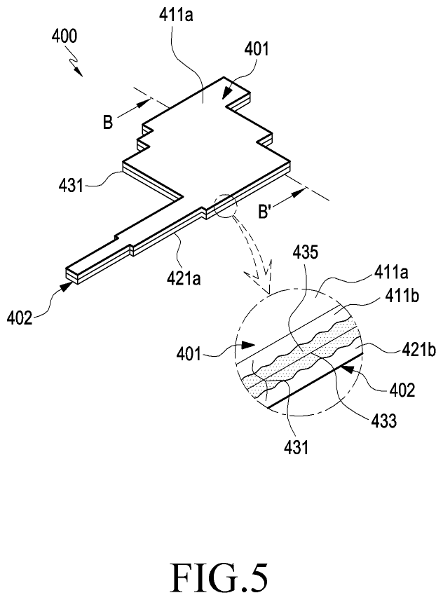

FIG. 5 is a perspective view illustrating a vapor chamber according to an embodiment of the disclosure.

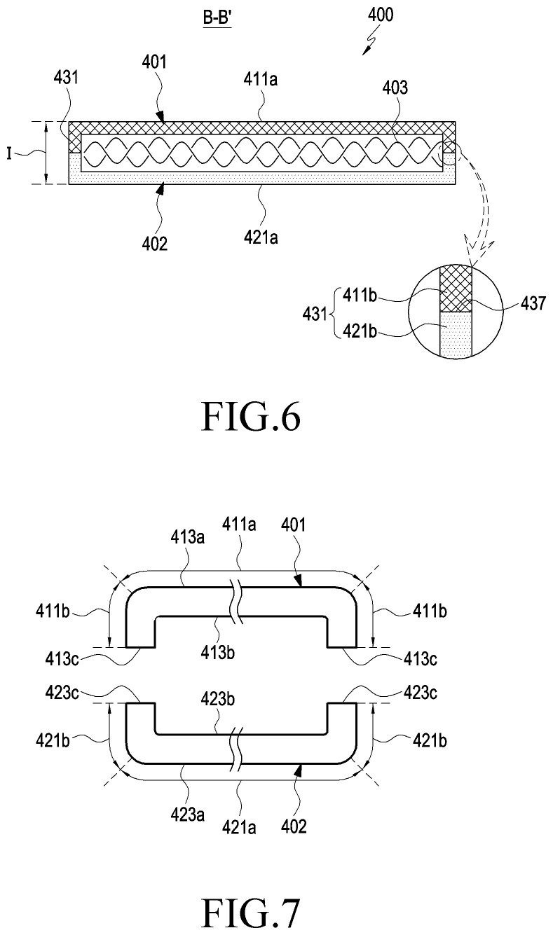

FIG. 6 is a cross-sectional view illustrating a configuration of a vapor chamber according to an embodiment of the disclosure. FIG. 6 is a cross-sectional view of vapor chamber 400, taken along line B-B′ of FIG. 5, according to an embodiment of the disclosure.

Referring to FIGS. 4 to 6, a heat dissipation structure, e.g., a vapor chamber 400, may form a sealing space by including a first sheet 401 and a second sheet 402, and the heat dissipation structure may include a supporting structure 403 and/or a wick structure 404 disposed in the sealing space. In one embodiment of the disclosure, the first sheet 401 and the second sheet 402 may include flat portions 411a and 421a and bending portions 411b and 421b, and may be coupled together to face each other to form the sealing space between the flat portions 411a and 421a. A cooling medium (or a working fluid) may be injected into the vapor chamber 400, and the cooling medium may be phase-changed depending on the external temperature to absorb, disperse, or release the heat generated from the heating component. For example, the cooling medium may be changed from the liquid phase to gaseous phase by absorbing the heat generated by the heat generating component, and the gaseous cooling medium may be changed back to a liquid by discharging the absorbed heat while moving inside the vapor chamber. For example, the cooling medium may circulate inside the vapor chamber 400 through the opening of the wick structure 404 according to a phase change (e.g., from a liquid phase (or gaseous phase) to a gaseous phase (or liquid phase)). In one embodiment of the disclosure, the cooling medium may include any one of water, a water-acetone mixture, and a water-ethanol mixture.

According to an embodiment of the disclosure, the second sheet 402 may absorb high-temperature heat from an electronic component (e.g., the integrated circuit chip 341 of FIG. 3) through a portion of the flat portion 421a. In one embodiment of the disclosure, the second sheet 402 may dissipate the absorbed high-temperature heat through another portion of the flat portion 421a. In an embodiment of the disclosure, the second sheet 402 may be formed in a shape corresponding to the shape of the electronic component, considering at least a portion of one surface of the flat portion 421a being in contact with the electronic component. In one embodiment of the disclosure, the second sheet 402 may be formed in a shape that may receive the wick structure 404, considering that the wick structure 404 is disposed on at least a portion of the other surface of the flat portion 421a.

According to an embodiment of the disclosure, the first sheet 401 and the second sheet 402 may be at least partially formed of stainless steel. For example, the first sheet 401 and the second sheet 402 may be formed of a stainless steel material of a low carbon steel material of 316L (low) (or 304L) (e.g., austenite-based). For example, if stainless steel is bonded at a high temperature, it may be corroded due to the inhibition of oxide film formation by the chemical reaction of carbon (C) and chromium (Cr), so it needs to be formed of a low-carbon steel material. According to an embodiment of the disclosure, the first sheet 401 and the second sheet 402 may at least partially include a material having thermal conductivity. For example, the first sheet 401 and the second sheet 402 may include at least one of graphite, carbon nanotubes, natural regenerated material, silicone, or silicon.

According to various embodiments of the disclosure, the supporting structure 403 may support the first sheet 401 and the second sheet 401 so that the shape of the internal space (e.g., sealing space) formed between the first sheet 401 and the second sheet 402 is maintained. In one embodiment of the disclosure, the supporting structure 403 may be formed in a pillar shape. In one embodiment of the disclosure, the supporting structure 403 may have a first side connected to the first sheet 401 and a second side connected to the wick structure 404 adjacent to the second sheet 402, in the internal space formed by the coupling of the first sheet 401 and the second sheet 402.

According to various embodiments of the disclosure, the wick structure 404 (e.g., a wick) may include at least one of a plurality of wires, an opening, and a passage to circulate the cooling medium (or working fluid) using the high-temperature heat transferred from the first sheet 401 and/or the second sheet 402. For example, the plurality of wires may be formed of a 316L (or 304L) low-carbon stainless steel material, copper, and/or a copper alloy (Cu alloy). The wires constituting the wick structure 404 may be formed in a straight line, a curved line, or a mesh structure.

According to various embodiments of the disclosure, the first sheet 401 may include a first flat portion 411a and a first bending portion 411b, and the second sheet 402 may include a second flat portion 421a and a second bending portion 421b. In one embodiment of the disclosure, the first bending portion 411b may be bent from the edge of the first flat portion 411a to be inclined at a first angle from the first flat portion 411a. The first angle may mean, e.g., about 90 degrees, and may be appropriately changed according to specifications required by the electronic device (e.g., the electronic device 300 of FIG. 3). In another embodiment of the disclosure, the second bending portion 421b may be inclined from the edge of the second flat portion 421a to be inclined at a second angle from the second flat portion 421a. The second angle may mean, e.g., about 90 degrees, and may be appropriately changed according to specifications required by the electronic device (e.g., the electronic device 300 of FIG. 3). Regarding the first sheet 401 and the second sheet 402, e.g., the side surface 431, the boundary line 433, the weld mark 435 and/or the bonding surface 437 of the vapor chamber 400 are described with reference to FIG. 7.

FIG. 7 is a view illustrating a configuration of sheets of a vapor chamber according to an embodiment of the disclosure.

Referring to FIG. 7, the first sheet 401 may include a first outer surface 413a, a first inner surface 413b and/or a first end face 413c connecting the first inner surface 413b to the first outer surface 413a. The first flat portion 411a may be formed by a portion of the first outer surface 413a and a portion of the first inner surface 413b. The first bending portion 411b may include a portion of the first outer surface 413a and a portion of the first inner surface 413b at the edge of the first sheet 401, and the first end face 413c may be substantially a portion of the first bending portion 411b. In one embodiment of the disclosure, the second sheet 402 may include a second outer surface 423a, a second inner surface 423b, and/or a second end face 423c connecting the second inner surface 423b to the second outer surface 423a. The second flat portion 421a may be formed by a portion of the second outer surface 423a and a portion of the second inner surface 423b. The second bending portion 421b may include a portion of the second outer surface 423a and a portion of the second inner surface 423b at the edge of the second sheet 402, and the second end face 423c may be substantially a portion of the second bending portion 421b.

According to various embodiments of the disclosure, the vapor chamber 400 may form a sealing space by substantially bonding the first end face 413c and the second end face 423c. For example, a bonding surface 437 may be formed between the first bending portion 411b and the second bending portion 421b as the first end face 413c and the second end face 423c are bonded together, and the first inner surface 413a and the second inner surface 423a may be coupled together to form the sealing space. According to an embodiment of the disclosure, the vapor chamber 400 may include a side portion 431 formed by bonding the first bending portion 411b and the second bending portion 421b, and the side portion 431 may seal the space between the first flat portion 411a and the second flat portion 421a. In another embodiment of the disclosure, the bonding surface 437 may be disposed at an angle from or perpendicular to the side portion 431. In another embodiment of the disclosure, if the first angle or the second angle is about 90 degrees, the outer surface of the side portion 431 may have a substantially flat shape.

According to various embodiments of the disclosure, as the first sheet 401 and/or the second sheet 402 includes the flat portions 411a and 421a and the bending portions 411b and 421b, at least the flat portions 411a and 421a may maintain the substantially flat plate shape. In another embodiment of the disclosure, since the bending portions 411b and 421b are bonded so that the first sheet 401 and the second sheet 402 to be coupled, the vapor chamber 400 may maintain the substantially flat plate shape more stably. For example, as compared to a structure including only the flat portions 411a and 421a, the vapor chamber 400 may have enhanced resistance to bending deformation as the first sheet 401 and/or the second sheet 402 includes the bending portions 411b and 421b.

According to various embodiments of the disclosure, given ease of formation or fabrication or heat dissipation performance, the vapor chamber 400 may be formed of a metal, such as copper or aluminum. However, in the small electronic device 300, such as a smart phone, the narrow space in which the vapor chamber 400 may be disposed may limit the thickness of the vapor chamber 400. For example, if the vapor chamber 400 is manufactured of a metal, e.g., copper or aluminum, in a limited thickness, it may be limited to secure a mechanical strength of the vapor chamber 400. For example, the vapor chamber 400 formed of a metal, such as copper or aluminum, may be vulnerable to bending deformation due to external impact if its thickness is reduced. According to various embodiments of the disclosure, as the vapor chamber 400, e.g., the first sheet 401 and/or the second sheet 402, includes stainless steel, the vapor chamber 400 may have sufficient mechanical strength although made thin. According to an embodiment of the disclosure, the first sheet 401 and/or the second sheet 402 may be formed of austenitic stainless steel containing about 18%-20% chromium and about 8%-12% nickel.

According to various embodiments of the disclosure, the metallic sheet, such as of copper or aluminum, may be easily bonded through a process, such as brazing or diffusion boding. For example, brazing may bond the sheets by heating and melting a filler at a predetermined temperature (e.g., 450 degrees Celsius) and injecting it into the gap between the sheets using a capillary phenomenon. As compared with welding or diffusion bonding, brazing does not melt the base material (e.g., the sheets) and is thus less likely to cause thermal deformation but may suffer from low bonding strength. Diffusion bonding may bond the sheets by applying a certain degree of temperature and pressure to the contact portions between the sheets. However, in bonding the first sheet 401 and/or the second sheet 402 including stainless steel, diffusion bonding applies temperature and pressure for a long time to secure a stable bonding strength. Thus, it may suffer from poor productivity.

According to various embodiments of the disclosure, in manufacturing the vapor chamber 400, the side portion 431 (e.g., the first bending portion (411b) and the second bending portion (421b)) may be irradiated with a laser beam and welded. For example, the first sheet 401 and the second sheet 402 may be bonded by irradiating a laser beam to the contact portion between the first bending portion 411b and the second bending portion 421b, with the first end face 413c and the second end face 423c in contact with each other. According to an embodiment of the disclosure, the first sheet 401 and the second sheet 402 may be bonded within a short time by irradiating a fiber laser with high energy density and/or ease of control of energy density. For example, by increasing the energy density of the laser irradiation, the bonding portion (the contact portion between the first bending portion 411b and the second bending portion 421b) may be melted and/or bonded faster than by diffusion bonding and, as the first sheet 401 and the second sheet 402 are melted and/or bonded, an enhanced bonding strength may be obtained than by brazing or diffusion bonding. For example, as compared to brazing or diffusion bonding, laser welding may enable local heating, which may reduce the fusional zone (FZ) or heat affected zone (HAZ) in the welding process, and may concentrate energy onto a narrow area, thus allowing for deeper welding with a low heat input. In some embodiments of the disclosure, laser welding may suppress unnecessary thermal deformation in areas other than the fusional zone, through local heating. For example, as compared to brazing or diffusion bonding, laser welding may enhance productivity by reducing processing time and may enhance welding quality or manufacturing flexibility while providing a high weld aspect ratio.

According to various embodiments of the disclosure, the vapor chamber 400 may include a boundary line 433 (e.g., a boundary line between the first bending portion 411b and the second bending portion 421b) formed on a side surface (e.g., the side portion 431). In some embodiments of the disclosure, the first bending portion 411b and the second bending portion 421b are welded together by laser welding, so that at least a portion of the boundary line 433 may not be noticeable with the naked eye. It is possible to promote the bonding of the contact surfaces (e.g., the first end face 413c and the second end face 423c) of the first sheet 401 and the second sheet 402 by adjusting the area (or width) of the laser irradiation or performing wobble welding depending on the thickness or material of the first sheet 401 and the second sheet 402.

According to various embodiments of the disclosure, the side portion 431 may include the laser-irradiated area or a weld mark 435 formed in the outer surface by wobble welding. ‘Weld mark 435’ is a trace of surface deformation in the laser-irradiated area in the first outer surface 413a and/or the second outer surface 423a and may have a pattern or color different from that of an area other than the laser-irradiated area. In one embodiment of the disclosure, the boundary line 433 between the first bending portion 411b and the second bending portion 421b may be located within the area with the weld mark 435. The weld mark 435 or the boundary line 433 may be formed substantially along the outer surface of the side portion 431 and, of the weld mark 435 and the boundary line 433, at least the welding mark 435 may form a closed curve. For example, laser welding may be performed along the entire edge of the first sheet 401 and the second sheet 402 (e.g., the first bending portion 411b and the second bending portion 421b). In various embodiments of the disclosure, the vapor chamber 400 including stainless steel may be manufactured by bonding the first sheet 401 and the second sheet 402 through laser irradiation along a welding path in a lateral direction. The welding path is not limited to the shape of the vapor chamber disclosed herein, and may include any proper number of paths arranged in a polygonal or non-polygonal shape. Additionally or alternatively, each segment itself may have a linear or non-linear (e.g., curved) shape, or each segment may have linear and non-linear portions. In various embodiments of the disclosure, the welding path may be configured to provide the vapor chamber 400 having a perimeter of a desired shape. In other embodiments of the disclosure, a laser or other suitable bonding device (e.g., electron beams or friction welding) may be used in bonding the vapor chamber 400.

According to various embodiments of the disclosure, the bonding surface 437 may be formed by bonding the first end face 413c and the second end face 423c to substantially face each other by laser welding. In some embodiments of the disclosure, with the first bending portion 411b and the second bending portion 421b welded together, the bonding surface 437 may have a bent or curved, rather than flat, shape and may be formed to be inclined from or perpendicular to the outer surface of the side surface 431. According to an embodiment of the disclosure, the thickness of the vapor chamber 400, e.g., the gap (e.g., the gap I of FIG. 6) between the outer surface (e.g., a portion of the first outer surface 413a) of the first flat portion 411a and the outer surface (e.g., a portion of the second outer surface 423a) of the second flat portion 421a, may be about 0.18 mm or more and 0.4 mm or less. For example, the vapor chamber 400 may be manufactured to have a fairly thin thickness, and may be easily installed inside the small electronic device 300. Although it is possible to manufacture the vapor chamber 400 of 0.4 mm or less using a metal, such as copper or aluminum, it may be vulnerable to bending deformation due to weak mechanical strength. According to various embodiments of the disclosure, the vapor chamber 400 may be formed of sheets 401 and 402 including stainless steel, and the structure of the bending portions 411b and 421b formed on the edges of the sheets 401 and 402 and/or the structure of the bending portions 411b and 421b welded by laser welding may contribute to securing a mechanical strength (e.g., resistance to bending deformation) for the sheets 401 and 402 and/or the vapor chamber 400.

According to various embodiments of the disclosure, a supporting structure (e.g., the supporting structure 403 of FIG. 4) may be received between the first sheet 401 and the second sheet 402, maintaining the gap between the first sheet 401 and the second sheet 402. For example, even when the first sheet 401 and the second sheet 402 are formed to have a fairly thin thickness, the shape or sealing space of the vapor chamber 400 may be stably maintained. The supporting structure 403 may be formed, e.g., by combining wavy metal wires or metal ribbons.

According to various embodiments of the disclosure, the wick structure (e.g., the wick structure 404 of FIG. 4) may have a capillary structure and may absorb the liquid cooling medium. In disposing the vapor chamber 400, the wick structure 404 may be disposed adjacent to a heat generating component (e.g., the integrated circuit chip 341 of FIG. 3), and the cooling medium absorbed by the wick structure 404 may absorb the heat generated by the heat generating component and be phase changed. The cooling medium which has absorbed heat, e.g., the liquid cooling medium, may discharge heat in relatively low temperature areas while circulating inside the vapor chamber 400 and be again phase changed to be able to absorb the heat generated by the heat generating component. The wick structure 404 may use a capillary structure to absorb the liquid cooling medium and may provide an environment in which the cooling medium may be exposed to the heat generated by the heat generating component over a larger surface area. For example, the wick structure 404 may promote a phase change of the cooling medium. According to various embodiments of the disclosure, the wick structure 404 may be shaped so that a capillary pressure corresponding to the internal pressure and/or a flow resistance corresponding to a pressure drop of the cooling medium (or working fluid) meet a designated value (e.g., a positive integer). For example, the wick structure 404 may have a different capillary pressure and/or flow resistance depending on a wire structure or a mesh structure, and accordingly, the shape of the wick structure 404 (e.g., the width of the opening of the mesh structure) may vary.

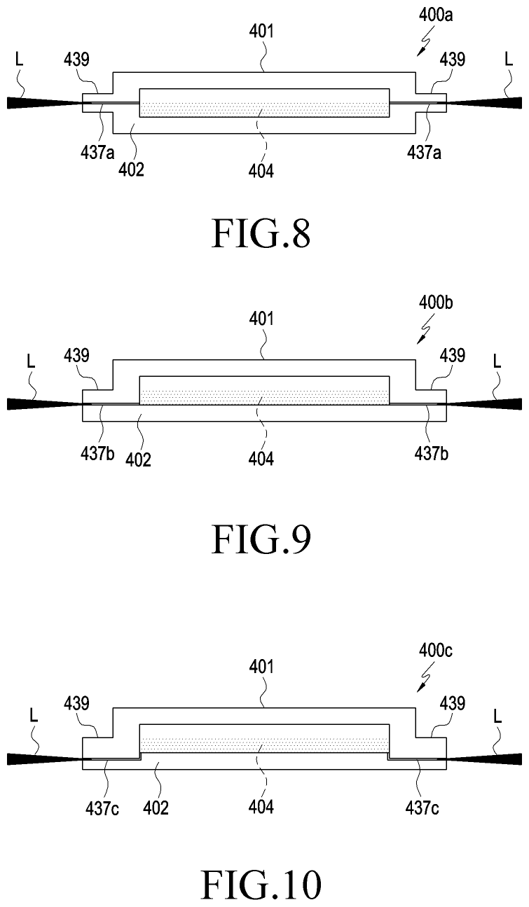

FIGS. 8 to 15 are views illustrating a formation structure of a bonding surface of a vapor chamber according to various embodiments of the disclosure.

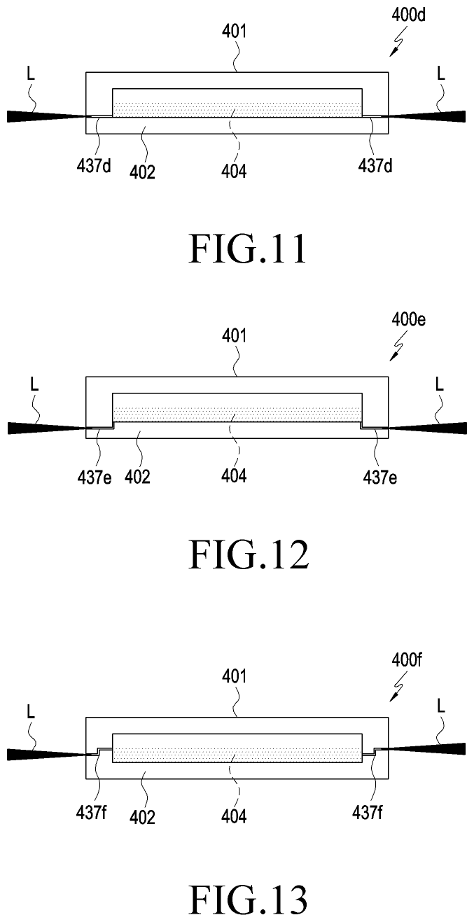

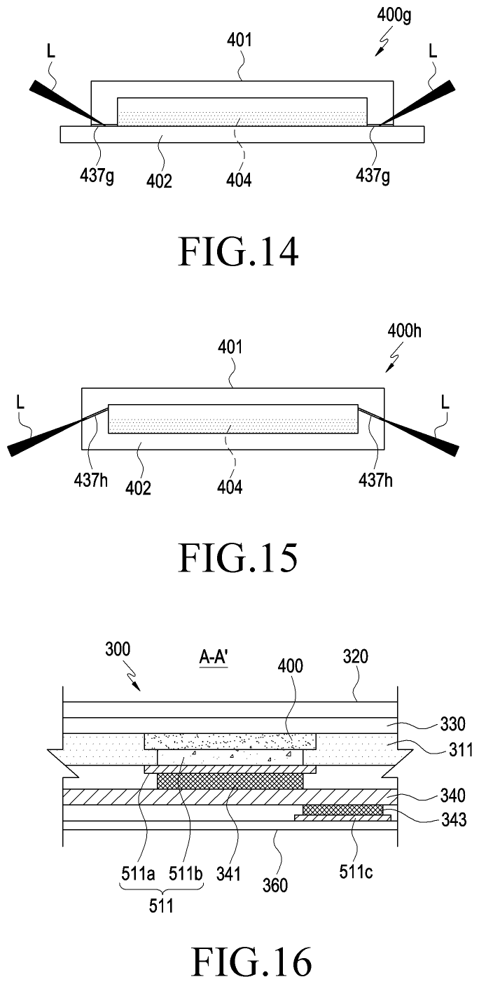

Referring to FIGS. 8 to 10, in the vapor chambers 400a, 400b, and 400c, at least one of the first sheet 401 and the second sheet 402 may include an extension 439 protruding from a side surface (e.g., the first bending portion 411b and/or the second bending portion 421b of FIG. 7). The extension portion 439 is a structure that substantially further expands the bonding surface 437a, 437b, or 437c than in one embodiment (e.g., the embodiment of FIG. 6), and may more securely bond the first sheet 401 and the second sheet 402. For example, the extension 439 may be a portion which is irradiated with a laser L and bonded. In some embodiments of the disclosure, as illustrated in FIG. 10, the bonding surface 437c between the first sheet 401 and the second sheet 402 may be formed in an ‘L’ shape. Referring to FIG. 11, in the vapor chamber 400d, any one (e.g., the second sheet 402) of the first sheet 401 and the second sheet 402 may have a flat plate shape, and the bending portion (e.g., the first bending portion 411b of FIG. 7) of the other one (e.g., the first sheet 401) of the first sheet 401 and the second sheet 402 may be bonded to the inner surface (e.g., the second inner surface 423b of FIG. 7) of the second sheet 402, forming the bonding surface 437d. As the first sheet 401 is bonded to the flat plate-shaped second sheet 402, an L-shaped bonding surface 437e may be formed between the first sheet 401 and the second sheet 402 in the vapor chamber 400e as illustrated in FIG. 12. Referring to FIG. 13, in the vapor chamber 400f, the bonding surface 437f between the first sheet 401 and the second sheet 402 may be formed in a stepped shape. For example, as the first end face 413c of the first sheet 401 and the second end face 423c of the second sheet 402 each have a stepped shape, the area of the bonding surface 437f may increase as compared with when the end faces have a flat shape (e.g., the shape shown in FIG. 7), providing enhanced bonding force. Referring to FIG. 14, in the vapor chamber 400g, the bending portion 411b of the first sheet 401 may be bonded to the inner surface of the second sheet 402 while being spaced apart from the edge of the second sheet 402 by a predetermined gap, forming a bonding surface 437g. In this case, in performing laser welding, the laser L may be irradiated in a direction inclined from the inner surface of the second sheet 402. Referring to FIG. 15, in the vapor chamber 400h, the first sheet 401 and the second sheet 402 may include bending portions 411b and 421b, respectively, and the end faces (e.g., the end faces 413c and 423c of FIG. 7) may have inclined surfaces 437h that are inclined from the flat portions (e.g., the flat portions 411a and 421a of FIG. 7). With the first sheet 401 and the second sheet 402 disposed to face each other, the end faces may come in surface contact with each other, and the laser L may be irradiated from the inclined directions of the end faces to bond the first sheet 401 and the second sheet. As such, the shape or position of the bonding surface between the first sheet 401 and the second sheet 402 may be varied, and may be appropriately selected considering the bonding force between the first sheet 401 and the second sheet 402 or the shape of the space in which the vapor chamber 400 is to be disposed.

FIG. 16 is a view illustrating a configuration in which a vapor chamber is disposed in an electronic device according to an embodiment of the disclosure.

Referring to FIG. 16, the components easy to understand from the description of an embodiment are denoted with the same reference numerals or without reference numerals and their detailed description may be skipped. FIG. 16 is a view illustrating a configuration of a portion of an electronic device, e.g., the electronic device 300 taken along line A-A′ of FIG. 3. Referring to FIG. 16, the electronic device 300 (e.g., the external electronic device 100, 300, 801, 802, or 804 of FIGS. 1 to 3 and/or 19) may include a heat dissipation structure (e.g., the vapor chamber 400) disposed adjacent to a heat generating component, e.g., an integrated circuit chip(s) 341 and 343 including a processor (e.g., the processor 820 of FIG. 19) or a communication module (e.g., the communication module 890 of FIG. 19). The integrated circuit chips 341 and 343 may be disposed, e.g., on one surface and/or the other surface, respectively, of the circuit board 340, or the plurality of integrated circuit chips 341 and 343 may be disposed on at least one surface of the circuit board 341. For example, the plurality of integrated circuit chips 341 and 343 may be disposed inside the electronic device 300 and, given the space or shape of the housing (e.g., the housing 110 of FIG. 1), may be appropriately distributed on the two opposite surfaces of the circuit board 340.

According to various embodiments of the disclosure, a first integrated circuit chip 341 among the integrated circuit chips 341 and 343 may be disposed on the circuit board 340 in the direction toward the front plate 320, and a first supporting member 311 may be disposed between the front plate 320 and/or display 330 and the circuit board 340. In one embodiment of the disclosure, the vapor chamber 400 may be disposed between the first supporting member 311 and the display 330 in a position adjacent to the heat generating component, e.g., the first integrated circuit chip 341, and may absorb the heat generated from the first integrated circuit chip 341 through a path passing through the first supporting member 311. In an embodiment of the disclosure, the electronic device 300 may include a heat transfer member 511 that transfers the heat generated from the first integrated circuit chip 341 to the vapor chamber 400. The heat transfer member 511 may include, e.g., a first heat transfer member 511a disposed between the first supporting member 311 and the first integrated circuit chip 341 and a second heat transfer member 511b received in the first supporting member 311.

According to various embodiments of the disclosure, the first heat transfer member 511a may be, e.g., a thermally conductive double-sided tape that may attach the first integrated circuit chip 341 to the first supporting member 311. In some embodiments of the disclosure, the first heat transfer member 511a may be a thermally conductive elastomer, which does not attach the first integrated circuit chip 341 to the first supporting member 311 but may be compressed to come in tight contact with the first integrated circuit chip 341 and the first supporting member 311. According to an embodiment of the disclosure, the second heat transfer member 511b may be a part of the first supporting member 311 and may tightly contact the first heat transfer member 511a and the vapor chamber 400. For example, the heat generated from the first integrated circuit chip 341 may be transferred to the vapor chamber 400 through the heat transfer member 511, and the cooling medium may discharge the heat in the vapor chamber 400 while being phase changed. The heat discharged from the vapor chamber 400 may be diffused or dispersed through, e.g., the first supporting member 311. As such, the vapor chamber 400 may absorb the heat generated from any one side (e.g., the direction in which the first integrated circuit chip 341 is disposed) and discharge the heat in another direction (e.g., the direction toward the front plate 320 or the first supporting member 311), preventing degradation of the operating performance or power efficiency of the first integrated circuit chip 341 due to heat generation. In some embodiments of the disclosure, one vapor chamber 400 may absorb heat from a plurality of heat generating components and disperse the heat to other thermally conductive structures.

According to various embodiments of the disclosure, although not shown, a thermally conductive sheet may be disposed between the display 330 (e.g., the display module 860 of FIG. 19) and the first supporting member 311. The thermally conductive sheet may substantially attach the display 330 to the first supporting member 311, and may be disposed in contact with the vapor chamber 400. For example, the heat emitted from the vapor chamber 400 may be diffused or dispersed over a larger area through the thermally conductive sheet. In one embodiment of the disclosure, the thermally conductive sheet may absorb the heat from the vapor chamber 400 and transfer it to the first supporting member 311, thereby promoting diffusion or dispersion of heat. In some embodiments of the disclosure, since the heat dissipation effect may increase as the area where heat is diffused or dispersed increases, the thermally conductive sheet may have a size substantially corresponding to the total area of the display 330. In another embodiment of the disclosure, the thermally conductive sheet may function as a cushioning member in disposing the display 330 on the first supporting member 311.

According to various embodiments of the disclosure, the second integrated circuit chip 343 among the integrated circuit chips 341 and 343 may be disposed on the circuit board 341 in the direction toward the inner surface (e.g., the second supporting member 360 and/or the rear plate 380 of FIG. 3) of the housing 110. According to an embodiment of the disclosure, the electronic device 300 may further include a third heat transfer member 511c. The third heat transfer member 511c may be disposed between the second integrated circuit chip 343 and the second supporting member 360. For example, the third heat transfer member 511c may transfer the heat generated from the second integrated circuit chip 343 to the second supporting member 360. According to an embodiment of the disclosure, a vapor chamber (e.g., the vapor chamber 400 of FIGS. 4 to 6) may be further disposed between the third heat transfer member 511c and the second supporting member 360. For example, if the second integrated circuit chip 343 is a component that generates a similar degree of, or more, heat than the first integrated circuit chip 341, the additional vapor chamber (e.g., the vapor chamber 400 of FIG. 4 or 5) may be disposed in contact with the third heat transfer member 511c to diffuse and/or discharge heat.

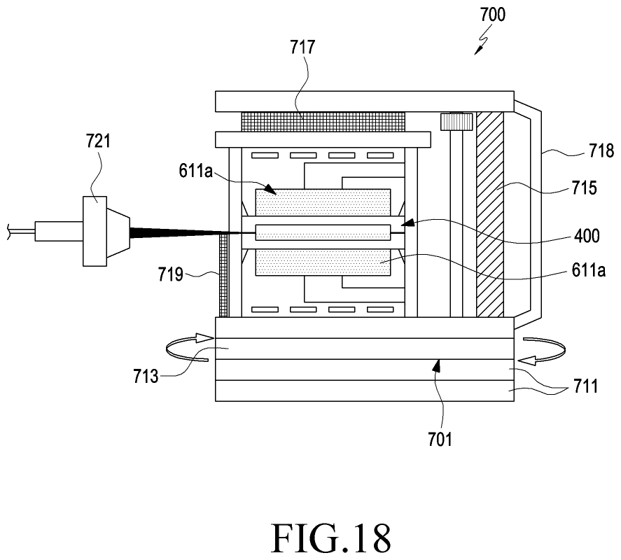

As such, according to various embodiments of the disclosure, the vapor chamber 400 may be disposed inside the electronic device 300, adjacent to the heat generating component (e.g., the integrated circuit chips 341 and 343 of FIG. 16) or between the inner surface (e.g., the front plate 320, the first supporting member 311, the rear plate 380 and/or the second supporting member 360 of FIG. 3) of the housing 110 and the heat generating component, and the vapor chamber 400 may disperse and/or discharge the heat generated from the heat generating component to other structures (e.g., the first supporting member 311, the second supporting member 360, and/or a thermally conductive sheet not shown). The vapor chamber 400 may be formed of sheets 401 and 402 substantially including stainless steel and may thus have resistance to bending deformation that may occur during an installation process. In some embodiments of the disclosure, since the sheets 401 and 402 are bonded by laser welding at the side portion 431, the vapor chamber 400 according to various embodiments of the disclosure may have a more stable bonding structure than a structure bonded by brazing and reduce the time required for bonding the sheets 401 and 402 as compared to diffusion bonding. According to an embodiment of the disclosure, it is possible to mitigate or prevent deformation of the sheets 401 and 402 due to heat applied during welding, as much as the time required for bonding is reduced. It is possible to more effectively suppress or prevent deformation of the sheets 401 and 402 due to the heat applied during welding by using the manufacturing equipment to be described below (e.g., the manufacturing equipment 700 of FIG. 18).

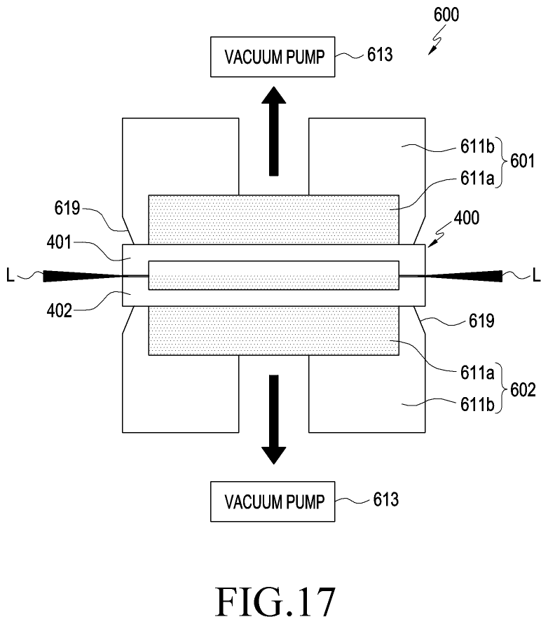

FIG. 17 is a view illustrating a vacuum chuck of a manufacturing equipment of a vapor chamber according to an embodiment of the disclosure.

Although the first sheet 401 or the second sheet 402 has resistance to bending deformation by including stainless steel or the bending portions 411b and 421b, the vapor chamber 400 may be deformed or lose adhesivity due to the residual stress during laser welding or during post-welding cooling. According to an embodiment of the disclosure, if heat is diffused to other areas of the sheets 401 and 402 outside the welding area or the bonding area during the welding process, the residual stress may increase in the vapor chamber 400 depending on the cooling conditions or environment, causing a shape or quality deviation between vapor chambers 400 individually manufactured. According to various embodiments of the disclosure, the manufacturing equipment 700 for manufacturing the vapor chamber 400 may suck the sheets 401 and 402 (e.g., the outer surfaces of the flat portions 411a and 421a) using a vacuum chuck 600 (e.g., a porous ceramic structure 611a), thereby rapidly dissipating the heat diffused to the areas off the bonding portion during welding and maintaining the flat portions 411a and 421a in the flat shape. For example, it is possible to maintain the vapor chamber 400 in a uniform shape or quality by suppressing heat diffusion to the areas off the bonding portion to suppress residual stress in the vapor chamber 400 during a post-welding cooling process.

Referring to FIG. 17, the vacuum chuck 600 for sucking the sheets 401 and 402 may include an upper chuck 601 and a lower chuck 602. The upper chuck 601 and the lower chuck 602 may have substantially the same configuration but different placement positions. The upper chuck 601 and the lower chuck 602 may include a frame structure 611b (e.g., a vacuum chamber) connected to a vacuum pump 613 and a porous ceramic structure 611a received in the frame structure 611b. A portion of the frame structure 611b and one surface of the porous ceramic structure 611a may form a surface on which the sheets 401 and 402 are sucked and, when the vacuum pump 613 operates, the porous ceramic structure 611a may substantially suck the sheets 401 and 402. In one embodiment of the disclosure, the porous ceramic structure 611a is a sintered ceramic body, such as of alumina, mullite, or silicon carbide, and may have pores having a size of about 2 microns to 3 microns. The sintered ceramic body has high strength and high porosity and may be combined with the vacuum pump 613 to enable high-precision suction. Further, the sintered ceramic body may be easily processed into a shape suitable for the shape of the designed vapor chamber 400 or the sheets 401 and 402. Further, the porous ceramic structure 611a may minimize post-processing surface damage by its own high hardness. According to an embodiment of the disclosure, the vacuum chuck 600 may have a scheme of clamping the target (e.g., the first sheet 401 and the second sheet 402) by sucking in the air through the open pores using the power of the vacuum pump 613, and the frame structure 611b may be formed of a metal, such as aluminum or stainless steel (e.g., steel special use stainless (SUS)).

According to various embodiments of the disclosure, the porous ceramic structure 611a may have a high thermal conductivity, e.g., a thermal conductivity of about 20 W/mK to 250 W/mK. For example, when the heat applied during welding is diffused to an area outside the bonding portion, the porous ceramic structure 611a sucking the sheets 401 and 402 may absorb and/or discharge heat. The frame structure 611b may substantially serve as a vacuum chamber. The inner space of the frame structure 611b connected to the vacuum pump 613 may be substantially filled with the porous ceramic structure 611a. In some embodiments of the disclosure, a plurality of channels may be formed on the inner wall of the frame structure 611b, and the channels may form a fluid movement path connected to the vacuum pump. For example, the suction force of the vacuum pump 613 may act on the entire porous ceramic structure 611a through the channels of the frame structure 611b and may act on the suction surface through the pores of the porous ceramic structure 611a to suck the sheets 401 and 402. In some embodiments of the disclosure, the suction force of the vacuum pump 613 may provide a cooling function that absorbs or discharges the heat that is diffused to areas outside the bonding portion during welding. Further, it is possible to mitigate the lifting phenomenon after welding by the cooling function through the plurality of channels.

According to various embodiments of the disclosure, before the first sheet 401 and the second sheet 402 are sucked up, the upper chuck 601 and the lower chuck 602 may be aligned by an alignment jig or alignment pins. In one embodiment of the disclosure, alignment pins may be disposed in a plurality of, e.g., two, three, or four, positions around the upper chuck 601 and the lower chuck 602 to align the upper chuck 601 and the lower chuck 602. In some embodiments of the disclosure, the upper chuck 601 and the lower chuck 602 may move toward or away from each other while being guided by the alignment pin(s). After the first sheet 401 and the second sheet 402 are sucked up, the alignment pins may be removed. In another embodiment of the disclosure, if alignment pins formed of a material, e.g., glass, that transmits a laser, are used, the alignment of the upper chuck 601 and the lower chuck 602 may be maintained even during the laser welding process.

According to various embodiments of the disclosure, the upper chuck 601 and the lower chuck 602 may suck the first sheet 401 and the second sheet 402 in the state of being aligned at the bonding position. The vacuum chuck 600 may maintain the bonding portions (e.g., the first bending portion 411b and second bending portion 421b of FIG. 4 or the first end face 413c and second end face 423c of FIG. 7) between the first sheet 401 and the second sheet 402, in the contacting state. In this state, the laser L is irradiated to the bonding portions (e.g., the first bending portion 411b and the second bending portion 421b of FIG. 4), so that the first sheet 401 and the second sheet 402 are bonded together. Further, according to various embodiments of the disclosure, since the laser L is irradiated to the side portion (e.g., the side portion 431 of FIG. 5) of the vapor chamber 400, there is no obstruction of the laser movement path, and thus, the bonding portions of the vapor chamber 400 may be welded with the vacuum chuck 600 using the porous ceramic structure 611a. For example, since heat transfer and/or cooling is performed symmetrically to the first sheet 401 and the second sheet 402 of the vapor chamber 400 by side irradiation, distortion caused by welding may be reduced.

According to various embodiments of the disclosure, the side surface of the vacuum chuck 600, e.g., the frame structure 611b, may be processed into an inclined surface 619 (e.g., chamfering) at a portion connected to the suction surface. For example, the suction surface of the vacuum chuck 600 may be made smaller than the flat portions (e.g., the flat portions 411a and 411b of FIG. 4). The inclined surface 619 of the frame structure 611b may prevent laser irradiation or heat application to the frame structure 611b during welding. For example, as the inclined surface 619 is formed, it is possible to prevent the frame structure 611b from being bonded to the sheets 401 and 402. Various inclinations or sizes of the inclined surface 619 may be set considering the energy density of the laser L irradiated to the sheets 401 and 402.

According to various embodiments of the disclosure, since the laser L is simultaneously irradiated to the sheets 401 and 402 (e.g., the bending portions 411b and 421b of FIG. 3), it is possible to reduce the time required for welding as compared with when the laser L is irradiated to any one of the sheets 401 and 402. For example, it is possible to suppress the diffusion of heat to the area beyond the bonding portion as much as the time required for welding is saved. In another embodiment of the disclosure, the vacuum pump 613 may be continuously operated while irradiating the laser L, and the porous ceramic structure 611a and/or the vacuum pump 613 may absorb or discharge the heat diffused to an area outside the bonding area during the welding process. For example, the porous ceramic structure 611a and/or the vacuum pump 613 may suppress or prevent residual stress from being generated due to the heat diffused to an unnecessary area during a post-welding cooling process.

FIG. 18 is a view illustrating manufacturing equipment of a vapor chamber according to an embodiment of the disclosure.

Referring to FIG. 18, the manufacturing equipment 700 may include a computer numerical control (CNC) stage 701 having four degrees of freedom and a light source 721. The vacuum chuck 600 may be disposed on the CNC stage 701. In some embodiments of the disclosure, the vacuum chuck 600 may be substantially part of the manufacturing equipment 700. The CNC stage 701 may include a 2-axis horizontal movement stage 711, a rotation stage 713, and a 1-axis vertical movement stage 715. For example, the vacuum chuck 600 and/or sheets (e.g., the vapor chamber 400) sucked to the vacuum chuck 600 may move in two horizontal directions with respect to the light source 721, or may rotate on the horizontal movement stage 711 or may move in the vertical direction. In some embodiments of the disclosure, welding may be performed while the vacuum chuck 600 may keep the first sheet 401 and the second sheet 402 in contact, and a pressure actuator 717 (e.g., a linear servo motor or a pneumatic cylinder), provided separately from the vertical movement stage 715, force the contact between the sheets 401 and 402. For example, when a pneumatic cylinder is used, a desired fixed pressure may be set through the valve, the pressure independently generated upon contact may be checked using a force transducer with a resolution of 30 N or less, and height may be adjusted using a displacement transducer having a range up to ±12.7 mm. For example, the fixing force may be uniformly applied by air pressure irrespective of the fixing path. According to an embodiment of the disclosure, when compressed air is unavailable or undesirable (e.g., as in a clean room), a servomotor may be used as a fixing device. In this case, the fixing force may be proportional to the current applied to the motor. For example, a linear module is configured as a rail system or screw that meets speed and precision requirements and may be integrated into a fixing jig frame. The device may be driven by a rotating stepper or brushless motor and may provide a moving speed of at least 100 mm/s and submicron repeatable positioning accuracy. For example, the fixing force (e.g., the force applied when it is mounted on the electronic device 300 of FIG. 3) may be limited to a maximum of 3 kg or less. For example, the force applied by the pressure actuator 717 may be limited to such an extent in which the surface of the vapor chamber 400 (e.g., the first sheet 401 and the second sheet 402) is not deformed (e.g., bent). In some embodiments of the disclosure, the manufacturing equipment 700 may include a vertical stopper 718 to prevent an excessive increase in the force clamping the first sheet 401 and the second sheet 402. For example, the vertical stopper 718 may limit the upper chuck (e.g., the upper chuck 601 of FIG. 17) from moving downward more than necessary to get closer to the lower chuck (e.g., the lower chuck 602 of FIG. 17). In another embodiment of the disclosure, if the clamping force is too low during welding, two portions (e.g., portions of the first sheet 401 and the second sheet 402) may fail to contact each other at some points. Thus, heat conductance in the bonding portions may not smoothly proceed during welding. Further, if the clamping pressure is reduced too early, a gap or only slight adhesion may be created before the bonding portions are sufficiently solidified.

According to various embodiments of the disclosure, the light source 721 may be, e.g., a fiber laser light source, and may irradiate a laser L having a high energy density. The light source 721 may adjust the position of irradiation of the laser L while moving in a horizontal direction or a vertical direction. In one embodiment of the disclosure, wobble welding in which the focus of the laser L is rapidly vibrated in various patterns may be performed. Considering the material or thickness of the sheets 401 and 402, the frequency, amplitude, spot size, wobble diameter, and/or linear welding speed of the irradiated laser L may be appropriately adjusted. In some embodiments of the disclosure, since the sheets 401 and 402 are capable of horizontal and vertical movement and/or rotation on the CNC stage 701, the light source 721 may remain stationary. In some embodiments of the disclosure, the CNC stage 701 may detect the position of the irradiation of the laser L by further including a position detection sensor 719. The position of the light source 721 or the sheets 401 and 402 may be adjusted based on the detected information.

As described above, it is possible to reduce the time required for welding and suppress or prevent heat diffusion to areas outside the bonding portions by simultaneously heating and/or welding the bending portions 411b and 421b of the bonding portions, from the side surfaces thereof, with the bending portions 411b and 421b of the sheets 401 and 402 in contact with each other. For example, it is possible to remove the cause that may substantially generate residual stress in the welding/cooling process by preventing heat from diffusing to areas outside the boding portions. In some embodiments of the disclosure, the vacuum chuck 600 may rapidly absorb or discharge the heat diffused to the areas outside the bonding portions and perform welding while maintaining the flatness of the sheets 401 and 402 (e.g., the flat portions 411a and 421a of FIG. 7).

FIG. 19 is a block diagram illustrating an electronic device in a network environment according to an embodiment of the disclosure.

Referring to FIG. 19, the electronic device 801 in the network environment 800 may communicate with the external electronic device 802 via a first network 898 (e.g., a short-range wireless communication network), or an electronic device 804 or a server 808 via a second network 899 (e.g., a long-range wireless communication network). According to an embodiment of the disclosure, the electronic device 801 may communicate with the electronic device 804 via the server 808. According to an embodiment of the disclosure, the electronic device 801 may include a processor 820, a memory 830, an input module 850, a sound output module 855, a display module 860, an audio module 870, a sensor module 876, an interface 877, a connecting terminal 878, a haptic module 879, a camera module 880, a power management module 888, a battery 889, a communication module 890, a subscriber identification module (SIM) 896, or the antenna module 897. In some embodiments of the disclosure, at least one (e.g., the connecting terminal 878) of the components may be omitted from the electronic device 801, or one or more other components may be added in the electronic device 101. According to an embodiment of the disclosure, some (e.g., the sensor module 876, the camera module 880, or the antenna module 897) of the components may be integrated into a single component (e.g., the display module 860).

The processor 820 may execute, for example, software (e.g., a program 840) to control at least one other component (e.g., a hardware or software component) of the electronic device 801 coupled with the processor 820, and may perform various data processing or computation. According to one embodiment of the disclosure, as at least part of the data processing or computation, the processor 820 may store a command or data received from another component (e.g., the sensor module 876 or the communication module 890) in a volatile memory 832, process the command or the data stored in the volatile memory 832, and store resulting data in a non-volatile memory 834. According to an embodiment of the disclosure, the processor 820 may include a main processor 821 (e.g., a central processing unit (CPU) or an application processor (AP)), or an auxiliary processor 823 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 801 includes the main processor 821 and the auxiliary processor 823, the auxiliary processor 823 may be configured to use lower power than the main processor 821 or to be specified for a designated function. The auxiliary processor 823 may be implemented as separate from, or as part of the main processor 821.

The auxiliary processor 823 may control at least some of functions or states related to at least one component (e.g., the display module 860, the sensor module 876, or the communication module 890) among the components of the electronic device 801, instead of the main processor 821 while the main processor 821 is in an inactive (e.g., sleep) state, or together with the main processor 821 while the main processor 821 is in an active state (e.g., executing an application). According to an embodiment of the disclosure, the auxiliary processor 823 (e.g., an image signal processor or a communication processor) may be implemented as part of another component (e.g., the camera module 880 or the communication module 890) functionally related to the auxiliary processor 123. According to an embodiment of the disclosure, the auxiliary processor 823 (e.g., the neural processing unit) may include a hardware structure specified for artificial intelligence model processing. The artificial intelligence model may be generated via machine learning. Such learning may be performed, e.g., by the electronic device 801 where the artificial intelligence is performed or via a separate server (e.g., the server 808). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 830 may store various data used by at least one component (e.g., the processor 820 or the sensor module 876) of the electronic device 801. The various data may include, for example, software (e.g., the program 840) and input data or output data for a command related thereto. The memory 830 may include the volatile memory 832 or the non-volatile memory 834.

The program 840 may be stored in the memory 830 as software, and may include, for example, an operating system (OS) 842, middleware 844, or an application 846.

The input module 850 may receive a command or data to be used by other component (e.g., the processor 820) of the electronic device 801, from the outside (e.g., a user) of the electronic device 801. The input module 850 may include, for example, a microphone, a mouse, a keyboard, keys (e.g., buttons), or a digital pen (e.g., a stylus pen).

The sound output module 855 may output sound signals to the outside of the electronic device 801. The sound output module 855 may include, for example, a speaker or a receiver. The speaker may be used for general purposes, such as playing multimedia or playing record. The receiver may be used for receiving incoming calls. According to an embodiment of the disclosure, the receiver may be implemented as separate from, or as part of the speaker.

The display module 860 may visually provide information to the outside (e.g., a user) of the electronic device 801. The display module 860 may include, for example, a display, a hologram device, or a projector and control circuitry to control a corresponding one of the display, hologram device, and projector. According to an embodiment of the disclosure, the display module 860 may include a touch sensor configured to detect a touch, or a pressure sensor configured to measure the intensity of a force generated by the touch.

The audio module 870 may convert a sound into an electrical signal and vice versa. According to an embodiment of the disclosure, the audio module 870 may obtain the sound via the input module 850, or output the sound via the sound output module 855 or a headphone of an external electronic device (e.g., the external electronic device 802) directly (e.g., wiredly) or wirelessly coupled with the electronic device 801.

The sensor module 876 may detect an operational state (e.g., power or temperature) of the electronic device 801 or an environmental state (e.g., a state of a user) external to the electronic device 101, and then generate an electrical signal or data value corresponding to the detected state. According to an embodiment of the disclosure, the sensor module 876 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 877 may support one or more specified protocols to be used for the electronic device 801 to be coupled with the external electronic device (e.g., the external electronic device 802) directly (e.g., wiredly) or wirelessly. According to an embodiment of the disclosure, the interface 877 may include, for example, a high definition multimedia interface (HDMI), a universal serial bus (USB) interface, a secure digital (SD) card interface, or an audio interface.

A connecting terminal 878 may include a connector via which the electronic device 801 may be physically connected with the external electronic device (e.g., the external electronic device 802). According to an embodiment of the disclosure, the connecting terminal 878 may include, for example, a HDMI connector, a USB connector, a SD card connector, or an audio connector (e.g., a headphone connector).

The haptic module 879 may convert an electrical signal into a mechanical stimulus (e.g., a vibration or motion) or electrical stimulus which may be recognized by a user via his tactile sensation or kinesthetic sensation. According to an embodiment of the disclosure, the haptic module 879 may include, for example, a motor, a piezoelectric element, or an electric stimulator.

The camera module 880 may capture a still image or moving images. According to an embodiment of the disclosure, the camera module 880 may include one or more lenses, image sensors, image signal processors, or flashes.

The power management module 888 may manage power supplied to the electronic device 801. According to one embodiment of the disclosure, the power management module 888 may be implemented as at least part of, for example, a power management integrated circuit (PMIC).

The battery 889 may supply power to at least one component of the electronic device 801. According to an embodiment of the disclosure, the battery 889 may include, for example, a primary cell which is not rechargeable, a secondary cell which is rechargeable, or a fuel cell.

The communication module 890 may support establishing a direct (e.g., wired) communication channel or a wireless communication channel between the electronic device 801 and the external electronic device (e.g., the external electronic device 802, the electronic device 804, or the server 808) and performing communication via the established communication channel. The communication module 890 may include one or more communication processors that are operable independently from the processor 820 (e.g., the application processor (AP)) and supports a direct (e.g., wired) communication or a wireless communication. According to an embodiment of the disclosure, the communication module 890 may include a wireless communication module 892 (e.g., a cellular communication module, a short-range wireless communication module, or a global navigation satellite system (GNSS) communication module) or a wired communication module 894 (e.g., a local area network (LAN) communication module or a power line communication (PLC) module). A corresponding one of these communication modules may communicate with the external electronic device via a first network 898 (e.g., a short-range communication network, such as Bluetooth™, wireless-fidelity (Wi-Fi) direct, or infrared data association (IrDA)) or a second network 899 (e.g., a long-range communication network, such as a legacy cellular network, a 5^{th} generation (5G) network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 892 may identify or authenticate the electronic device 801 in a communication network, such as the first network 898 or the second network 899, using subscriber information (e.g., international mobile subscriber identity (IMSI)) stored in the subscriber identification module 896.

The wireless communication module 892 may support a 5G network, after a 4^{th} generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 892 may support a high-frequency band (e.g., the mmWave band) to achieve, e.g., a high data transmission rate. The wireless communication module 892 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 892 may support various requirements specified in the electronic device 801, an external electronic device (e.g., the electronic device 804), or a network system (e.g., the second network 899). According to an embodiment of the disclosure, the wireless communication module 892 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 897 may transmit or receive a signal or power to or from the outside (e.g., the external electronic device). According to an embodiment of the disclosure, the antenna module may include an antenna including a radiator formed of a conductor or conductive pattern formed on a substrate (e.g., a printed circuit board (PCB)). According to an embodiment of the disclosure, the antenna module 897 may include a plurality of antennas (e.g., an antenna array). In this case, at least one antenna appropriate for a communication scheme used in a communication network, such as the first network 898 or the second network 899, may be selected from the plurality of antennas by, e.g., the communication module 890. The signal or the power may then be transmitted or received between the communication module 890 and the external electronic device via the selected at least one antenna. According to an embodiment of the disclosure, other parts (e.g., radio frequency integrated circuit (RFIC)) than the radiator may be further formed as part of the antenna module 897.

According to various embodiments of the disclosure, the antenna module 897 may form a mmWave antenna module. According to an embodiment of the disclosure, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment of the disclosure, commands or data may be transmitted or received between the electronic device 801 and the external electronic device 804 via the server 808 coupled with the second network 899. The external electronic devices 802 or 804 each may be a device of the same or a different type from the electronic device 801. According to an embodiment of the disclosure, all or some of operations to be executed at the electronic device 801 may be executed at one or more of the external electronic devices 802, 804, or 808. For example, if the electronic device 801 should perform a function or a service automatically, or in response to a request from a user or another device, the electronic device 801, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 801. The electronic device 801 may provide the outcome, with or without further processing of the outcome, as at least part of a reply to the request. To that end, a cloud computing, distributed computing, mobile edge computing (MEC), or client-server computing technology may be used, for example. The electronic device 801 may provide ultra low-latency services using, e.g., distributed computing or mobile edge computing. In another embodiment of the disclosure, the external electronic device 804 may include an internet-of-things (IoT) device. The server 808 may be an intelligent server using machine learning and/or a neural network. According to an embodiment of the disclosure, the external electronic device 804 or the server 808 may be included in the second network 899. The electronic device 801 may be applied to intelligent services (e.g., smart home, smart city, smart car, or health-care) based on 5G communication technology or IoT-related technology.

The electronic device according to various embodiments may be one of various types of electronic devices. The electronic devices may include, for example, a portable communication device (e.g., a smart phone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment of the disclosure, the module may be implemented in a form of an application-specific integrated circuit (ASIC).

Various embodiments as set forth herein may be implemented as software (e.g., the program 840) including one or more instructions that are stored in a storage medium (e.g., an internal memory 836 or an external memory 838) that is readable by a machine (e.g., the electronic device 801). For example, a processor (e.g., the processor 820) of the machine (e.g., the electronic device 801) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment of the disclosure, a method according to various embodiments of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments of the disclosure, each component (e.g., a module or a program) of the above-described components may include a single entity or multiple entities. Some of the plurality of entities may be separately disposed in different components. According to various embodiments of the disclosure, one or more of the above-described components may be omitted, or one or more other components may be added. Alternatively or additionally, a plurality of components (e.g., modules or programs) may be integrated into a single component. In such a case, according to various embodiments of the disclosure, the integrated component may still perform one or more functions of each of the plurality of components in the same or similar manner as they are performed by a corresponding one of the plurality of components before the integration. According to various embodiments of the disclosure, operations performed by the module, the program, or another component may be carried out sequentially, in parallel, repeatedly, or heuristically, or one or more of the operations may be executed in a different order or omitted, or one or more other operations may be added.

As described above, according to various embodiments of the disclosure, a vapor chamber (e.g., the vapor chamber 400 of FIGS. 4 to 6) and/or an electronic device (e.g., the electronic device 100 or 300 of FIGS. 1 to 3 and/or FIG. 16) comprises a first sheet (e.g., the first sheet 401 of FIGS. 4 to 7) including a first flat portion (e.g., the first flat portion 411a of FIGS. 4 to 7) and a first bending portion (e.g., the first bending portion 411b of FIGS. 4 to 7) bent, at an edge of the first flat portion, to be inclined at a first angle for the first flat portion, a second sheet (e.g., the second sheet 402 of FIGS. 4 to 7) including a second flat portion (e.g., the second flat portion 421a of FIGS. 4 to 7) and a second bending portion (e.g., the second bending portion 421b of FIGS. 4 to 7) bent, at an edge of the second flat portion, to be inclined at a second angle for the second flat portion, and a side portion (e.g., the side portion 431 of FIG. 5 and/or FIG. 6) formed by bonding the first bending portion and the second bending portion. A bonding surface (e.g., the bonding surface 437 of FIG. 6) between the first bending portion and the second bending portion may be disposed to be inclined from or perpendicular to an outer surface of the side portion.

According to various embodiments of the disclosure, the side portion may seal a space between the first flat portion and the second flat portion.

According to various embodiments of the disclosure, the first sheet or the second sheet may include stainless steel.

According to various embodiments of the disclosure, the vapor chamber and/or the electronic device may further comprise a weld mark (e.g., the weld mark 435 of FIG. 5) formed along the outer surface of the side portion. A boundary line (e.g., the boundary line 433 of FIG. 5) between the first bending portion and the second bending portion may be positioned in the weld mark in the outer surface of the side portion.

According to various embodiments of the disclosure, the vapor chamber and/or the electronic device may further comprise a wick structure (e.g., the wick structure 404 of FIG. 4) or a supporting structure (e.g., the supporting structure 403 of FIG. 4 and/or FIG. 6) disposed in a space between the first flat portion and the second flat portion.

According to various embodiments of the disclosure, the first sheet may include a first outer surface (e.g., the first outer surface 413a of FIG. 7), a first inner surface (e.g., the first inner surface 413b of FIG. 7), and a first end face (e.g., the first end face 413c of FIG. 7) connecting the first inner surface to the first outer surface. The second sheet may include a second outer surface (e.g., the second outer surface 423a of FIG. 7), a second inner surface (e.g., the second inner surface 423b of FIG. 7), and a second end face (e.g., the second end face 423c of FIG. 7) connecting the second inner surface to the second outer surface. The first end face and the second end face may be bonded to face each other, forming the bonding surface between the first bending portion and the second bending portion.

According to various embodiments of the disclosure, a gap between the first outer surface and the second outer surface may be 0.18 mm or more and 0.4 mm or less.

According to various embodiments of the disclosure, the vapor chamber and/or the electronic device may further comprise a sealing space formed by coupling the first inner surface and the second inner surface.

According to various embodiments of the disclosure, the vapor chamber may further comprise a sealing space formed by coupling the first inner surface and the second inner surface, and a wick structure or a supporting structure disposed in the sealing space.

According to various embodiments of the disclosure, the vapor chamber and/or the electronic device may further comprise a weld mark formed along the outer surface of the side portion. A boundary line between the first outer surface and the second outer surface may be positioned in the weld mark in the outer surface of the side portion.

According to various embodiments of the disclosure, the first sheet or the second sheet may include stainless steel.

According to various embodiments of the disclosure, the first end face and the second end face may be bonded by laser welding.

According to various embodiments of the disclosure, an electronic device (e.g., the electronic device 100 or 300 of FIGS. 1 to 3 and/or FIG. 16) comprises a housing (e.g., the housing 110 of FIG. 1), a printed circuit board (e.g., the printed circuit board 340 of FIG. 3 and/or FIG. 16) received in the housing, at least one heat generating component (e.g., the integrated circuit chips 341 and 343 of FIG. 3 and/or FIG. 16) disposed on the printed circuit board, and at least one vapor chamber (e.g., the vapor chamber 400 of FIGS. 4 to 6 and/or FIG. 16) disposed adjacent to the heat generating component and configured to absorb, in a first direction, heat generated from the heat generating component and transfer or discharge the heat in a second direction different from the first direction. The vapor chamber may include a first sheet (e.g., the first sheet 401 of FIGS. 4 to 7) including a first flat portion (e.g., the first flat portion 411a of FIGS. 4 to 7) and a first bending portion (e.g., the first bending portion 411b of FIGS. 4 to 7) bent, at an edge of the first flat portion, to be inclined at a first angle for the first flat portion, a second sheet (e.g., the second sheet 402 of FIGS. 4 to 7) including a second flat portion (e.g., the second flat portion 421a of FIGS. 4 to 7) and a second bending portion (e.g., the second bending portion 421b of FIGS. 4 to 7) bent, at an edge of the second flat portion, to be inclined at a second angle for the second flat portion, and a side portion (e.g., the side portion 431 of FIG. 5 and/or FIG. 6) formed by bonding the first bending portion and the second bending portion. A bonding surface (e.g., the bonding surface 437 of FIG. 6) between the first bending portion and the second bending portion may be disposed to be inclined from or perpendicular to an outer surface of the side portion.

According to various embodiments of the disclosure, the vapor chamber may be disposed between an inner surface (e.g., the front plate 320 of FIG. 16, the second supporting member 360, and/or the rear plate 380 of FIG. 3) of the housing and the at least one heat generating component.

According to various embodiments of the disclosure, the electronic device may further comprise a heat transfer member (e.g., the heat transfer members 511a, 511b, and 511c of FIG. 16) disposed between the vapor chamber and the heat generating component.

According to various embodiments of the disclosure, the first sheet may include a first outer surface (e.g., the first outer surface 413a of FIG. 7), a first inner surface (e.g., the first inner surface 413b of FIG. 7), and a first end face (e.g., the first end face 413c of FIG. 7) connecting the first inner surface to the first outer surface. The second sheet may include a second outer surface (e.g., the second outer surface 423a of FIG. 7), a second inner surface (e.g., the second inner surface 423b of FIG. 7), and a second end face (e.g., the second end face 423c of FIG. 7) connecting the second inner surface to the second outer surface. The first end face and the second end face may be bonded to face each other, forming the bonding surface between the first bending portion and the second bending portion.

According to various embodiments of the disclosure, the vapor chamber may further comprise a sealing space formed by coupling the first inner surface and the second inner surface and a wick structure (e.g., the wick structure 404 of FIG. 4) or a supporting structure (e.g., the supporting structure 403 of FIG. 4 and/or FIG. 6) disposed in the sealing space.

According to various embodiments of the disclosure, the first sheet or the second sheet may include stainless steel.

According to various embodiments of the disclosure, the vapor chamber may further comprise a weld mark (e.g., the weld mark 435 of FIG. 5) formed along the outer surface of the side portion. A boundary line (e.g., the boundary line 433 of FIG. 5) between the first bending portion and the second bending portion may be positioned in the weld mark in the outer surface of the side portion.

According to various embodiments of the disclosure, a boundary line or the weld mark between the first bending portion and the second bending portion may be formed to form a closed curve.

While the disclosure has been shown and described with reference to various embodiments thereof, it will be understood by those skilled in the art that various changes in form and details may be made therein without departing from the spirit and scope of the disclosure as defined by the appended claims and their equivalents. For example, in the above-described embodiments of the disclosure, although configured to be bonded by laser welding as an example, the sheets may be bonded by diffusion bonding, electron beam welding, or friction welding. As mentioned above, if the sheets include stainless steel, laser welding may be more suitable as a manufacturing method than diffusion bonding in view of productivity, and this may be appropriately selected by those skilled in the art considering such factors as manufacturing time and costs.

1. A vapor chamber comprising:
a first sheet including a first flat portion and a first bending portion bent, at an edge of the first flat portion, to be inclined at a first angle for the first flat portion;
a second sheet including a second flat portion and a second bending portion bent, at an edge of the second flat portion, to be inclined at a second angle for the second flat portion; and
a side portion formed by bonding the first bending portion and the second bending portion,
wherein a bonding surface between the first bending portion and the second bending portion is disposed to be inclined from or perpendicular to an outer surface of the side portion.

2. The vapor chamber of claim 1, wherein the side portion is configured to seal a space between the first flat portion and the second flat portion.

3. The vapor chamber of claim 1, wherein the first sheet or the second sheet includes stainless steel.

4. The vapor chamber of claim 1, further comprising a weld mark formed along the outer surface of the side portion,
wherein a boundary line between the first bending portion and the second bending portion is positioned in the weld mark in the outer surface of the side portion.

5. The vapor chamber of claim 1, further comprising a wick structure or a supporting structure disposed in a space between the first flat portion and the second flat portion.

6. The vapor chamber of claim 1,
wherein the first sheet includes a first outer surface, a first inner surface, and a first end face connecting the first inner surface to the first outer surface,
wherein the second sheet includes a second outer surface, a second inner surface, and a second end face connecting the second inner surface to the second outer surface, and
wherein the first end face and the second end face are bonded to face each other, and configured to form the bonding surface between the first bending portion and the second bending portion.

7. The vapor chamber of claim 6, wherein a gap between the first outer surface and the second outer surface is 0.18 mm or more and 0.4 mm or less.

8. The vapor chamber of claim 6, further comprising a sealing space formed by coupling the first inner surface and the second inner surface.

9. The vapor chamber of claim 6, further comprising:
a sealing space formed by coupling the first inner surface and the second inner surface; and
a wick structure or a supporting structure disposed in the sealing space.

10. The vapor chamber of claim 6, further comprising a weld mark formed along the outer surface of the side portion,
wherein a boundary line between the first outer surface and the second outer surface is positioned in the weld mark in the outer surface of the side portion.

11. The vapor chamber of claim 6, wherein the first sheet or the second sheet includes stainless steel.

12. The vapor chamber of claim 11, wherein the first end face and the second end face are bonded by laser welding.

13. An electronic device comprising:
a housing;
a printed circuit board received in the housing;
at least one heat generating component disposed on the printed circuit board; and
at least one vapor chamber disposed adjacent to the at least one heat generating component and configured to absorb, in a first direction, heat generated from the at least one heat generating component and transfer or discharge the heat in a second direction different from the first direction,
wherein the at least one vapor chamber includes:
a first sheet including a first flat portion and a first bending portion bent, at an edge of the first flat portion, to be inclined at a first angle for the first flat portion,
a second sheet including a second flat portion and a second bending portion bent, at an edge of the second flat portion, to be inclined at a second angle for the second flat portion, and
a side portion formed by bonding the first bending portion and the second bending portion, and
wherein a bonding surface between the first bending portion and the second bending portion is disposed to be inclined from or perpendicular to an outer surface of the side portion.

14. The electronic device of claim 13, wherein the at least one vapor chamber is disposed between an inner surface of the housing and the at least one heat generating component.

15. The electronic device of claim 13, further comprising a heat transfer member disposed between the at least one vapor chamber and the at least one heat generating component.

16. The electronic device of claim 15, wherein the side portion is configured to seal a space between the first flat portion and the second flat portion.

17. The electronic device of claim 15, wherein the first sheet or the second sheet includes stainless steel.
